(19) United States
(12) Patent Application Publication
(10) Pub. No.: US 2012/0064308 A1
(43) Pub. Date: Mar. 15, 2012

(54) Sheet Having Convex Pattern on Surface and Method for Forming the Convex Pattern

(76) Inventors: Sadayuki Yoneshima, Hirakata-shi (JP); Mitsushi Sogabe, Katano-shi (JP); Hisao Aota, Nara-shi (JP); Masayuki Goryozono, Daito-shi (JP); Yumiko Omiya, Moriguchi-shi (JP)

(21) Appl. No.: 13/263,899

(22) PCT Filed: Apr. 8, 2010
(86) PCT No.: PCT/JP2010/056366

§ 371 Date: Oct. 11, 2011

(30) Foreign Application Priority Data
Apr. 13, 2009 (JP) 2009-096613

(51) Int. Cl. G03F 7/24; B32B 3/10; B32B 37/14; B32B 37/02; B32B 37/12

(52) U.S. Cl. 428/195.1; 430/325; 156/306.6

(57) ABSTRACT

A method for forming a convex pattern on a surface of a sheet includes the steps of covering a photosensitive resin film 21 with a masking film 4 having a convex forming area 40 corresponding to a convex pattern to be obtained, exposing the photosensitive resin film 21 to light from an outside of the masking film 4, and removing an unexposed portion of the photosensitive resin film 21 subjected to the exposing step, thereby forming a sheet 2 with an exposed portion 22 left, and the convex forming area 40 of the masking film 4 has a semi-translucent portion 43 and a translucent portion 41 formed in sequence at an outside of a light-shielding portion 42 in order to express a shade in gradation, and a light transmittance increases stepwise from the light-shielding portion 42 toward the translucent portion 41.

### CROSS-REFERENCE TO RELATED APPLICATION

This application is a U.S. National Stage filing of International Patent Application No. PCT/JP2010/056366 filed Apr. 8, 2010, which is an International filing of Japanese Patent Application No. 2009-096613 filed Apr. 13, 2009.

### TECHNICAL FIELD

The present invention relates to a sheet having a convex pattern on a surface and a method for forming the convex pattern.

### BACKGROUND ART

Interior equipment such as a dashboard of a car is formed by a synthetic resin in respect of a light weight, mass productivity and the like, and a fine convex pattern such as a satin finished surface or a leather grain is applied to a surface of the interior equipment in order to obtain a high-grade sense, a feeling of richness or warmth. The interior equipment formed by the resin can be easily molded by forming an inverted concave pattern of a convex pattern of a product on a metal mold plane in molding through etching or the like.

In a stage for manufacturing an experimental car to be displayed in an exhibition, however, it is hard to form a concave pattern on a metal mold in respect of problems of a cost, time and the like. For example, if the concave pattern is once formed on the metal mold, it is difficult to change the shape of the concave pattern and the like later. Accordingly, there is employed a method for pasting a sheet having a convex pattern formed thereon to a surface of a product such as an experimental car.

FIGS. 10 to 13 are views showing a method for manufacturing a sheet having a convex pattern formed thereon, which was proposed before by the applicant (see Patent Document 1). First of all, as shown in FIG. 10, a photosensitive resin film (21) to be a transparent body is backed with a thin resin film (3) having elasticity, that is, the thin resin film (3) is applied to the back of the photosensitive resin film (21). The thin resin film (3) has adhesive layers (31) and (32) on both upper and lower surfaces, and the adhesive layer (32) on the lower side is covered with a releasing paper (33).

As shown in FIG. 11, the photosensitive resin film (21) is covered with a masking film (4), and the masking film (4) is exposed to light emitted from a light source (5). As is well known, the masking film (4) has a translucent portion (41) and a light-shielding portion (42) formed thereon, and the light emitted from the light source (5) passes through the translucent portion (41) and cures a corresponding part of the photosensitive resin film (21). The cured part is an exposed portion (22). A part of the photosensitive resin film (21) shielded by the light-shielding portion (42) is not cured but an unexposed portion (23).

As shown in FIG. 12, after stopping the exposure, the masking film (4) is removed from the photosensitive resin film (21) and then the photosensitive resin film (21) is washed with a cleaning solution such as water in order to remove the unexposed portion (23). There is obtained a sheet (2) in which the exposed portions (22) are alternately arranged to form a convex pattern, and the releasing paper (33) is peeled off and the sheet (2) is stuck onto a product (1) as shown in FIG. 13. After the exposure, a coating (28) such as grain may be applied onto the whole surface of the exposed portion (22) and the thin resin film (3).

### PRIOR ART DOCUMENT

### Patent Document

Patent Document 1: Japanese Unexamined Patent Application Publication No. 2007-144898

### SUMMARY OF THE INVENTION

### Problems to be Solved by the Invention

In the sheet having the convex pattern formed thereon, heights of all the exposed portions (22) are almost equal to each other. For this reason, only a planar pattern can be formed as seen from above, that is, the height cannot be varied for each of the exposed portions (22). As shown in FIG. 12, moreover, an upper surface of the exposed portion (22) is square and a pattern to be appeared sometimes lacks softness and warmth.

It is an object of the present invention to provide a manufacturing method capable of varying a height for each of the exposed portions (22) or giving roundness to a corner portion of an upper surface of a convex pattern.

### Solutions to the Problems

A method for forming a convex pattern on a surface of a sheet includes the steps of covering a photosensitive resin film (21) with a masking film (4) having a convex forming area (40) corresponding to a convex pattern to be obtained, exposing the photosensitive resin film (21) to light from an outside of the masking film (4), and removing an unexposed portion of the photosensitive resin film (21) subjected to the exposing step, thereby forming a sheet (2) with an exposed portion (22) left, and the convex forming area (40) of the masking film (4) has a semi-translucent portion (43) and a translucent portion (41) formed in sequence at an outside of a light-shielding portion (42) having a shade expressed in gradation, and a light transmittance increases stepwise from the light-shielding portion (42) toward the translucent portion (41).

### Advantageous Effects of the Invention

In the exposure, light is applied from the outside of the convex forming area (40) of the masking film (4). The translucent portion (41) causes the light to be transmitted therethrough. Therefore, the portion of photosensitive resin film (21) corresponding to the translucent portion (41) is cured and the portion of photosensitive resin film (21) corresponding to the light-shielding portion (42) is not cured at all. The portion of photosensitive resin film (21) corresponding to the semi-translucent portion (43) is not cured perfectly and is to be a mixed state with a cured portion and an uncured portion.

When the unexposed portion is removed from the photosensitive resin film (21) subjected to the exposure, accordingly, a portion in which the cured portion and the uncured portion are mixed together takes a non-square shape. Consequently, it is possible to vary a height for each of the exposed portions (22) or to give roundness to a corner portion of an upper surface of a convex pattern.

### BRIEF DESCRIPTION OF THE DRAWINGS

FIG. 1 is a view showing a step of covering a photosensitive resin film with a masking film.

FIG. 2 is an enlarged view showing a side surface of a light-shielding portion according to the present embodiment.

FIG. 3 is a plan view showing the masking film in FIG. 1 as seen in an A direction.

FIG. 4 is a view showing an exposing step.

FIG. 5 is a view showing a photosensitive resin film subjected to an exposure.

FIG. 6 is a view showing another exposing step.

FIG. 7 is a view showing a relationship between a color and a light transmittance of ultraviolet ray.

FIG. 8 is a plan view showing a masking film according to another embodiment.

FIG. 9 is a plan view showing a masking film according to a further embodiment.

FIG. 10 is a view showing a conventional method for manufacturing a sheet having a convex pattern formed thereon.

FIG. 11 is a view showing the conventional method for manufacturing a sheet having a convex pattern formed thereon.

FIG. 12 is a view showing the conventional method for manufacturing a sheet having a convex pattern formed thereon.

FIG. 13 is a view showing a state in which a sheet having a convex pattern formed thereon is pasted onto a product.

### EMBODIMENTS OF THE INVENTION

An embodiment according to the present invention will be described below with reference to the drawings.

### First Embodiment

In the same manner as in the conventional art, the present embodiment relates to a method for manufacturing a sheet having a convex pattern formed thereon which is to be pasted onto a surface of a product such as an experimental car. The manufacturing method is schematically carried out in order of exposure to light from a back side and removal of an unexposed portion.

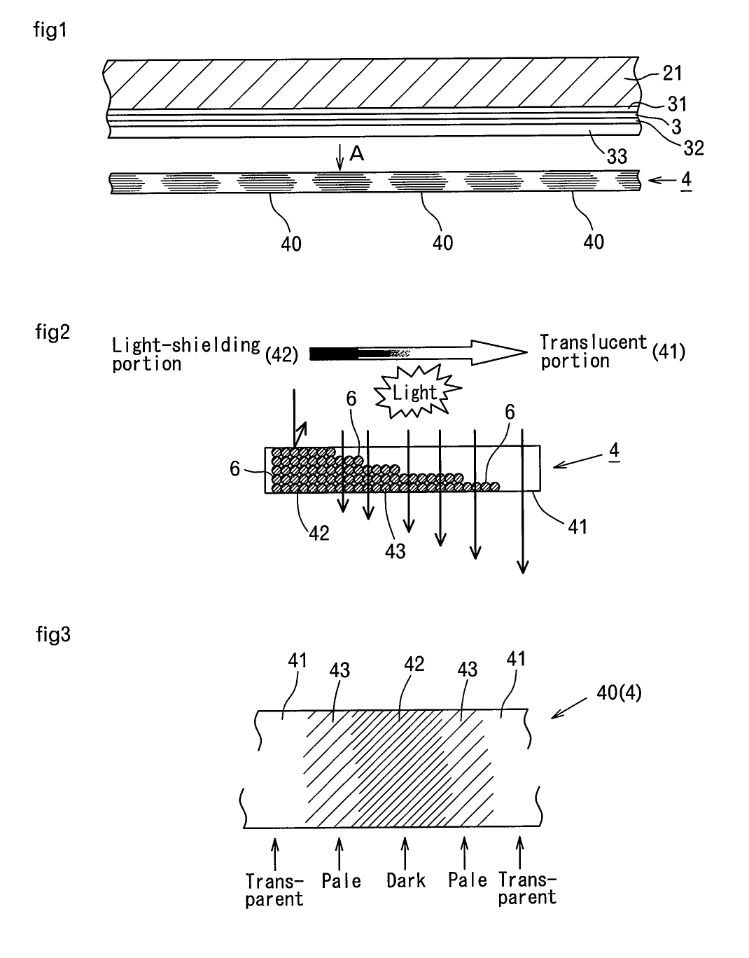

First of all, as shown in FIG. 1, a photosensitive resin film (21) to be a transparent body is prepared.

It is desirable that the photosensitive resin film (21) should have a thickness of 100 to 300 μm because it can easily be pasted onto a product (1) which is described below and images of the photosensitive resin film (21) and mass-produced goods in a metal mold are very close to each other. In the embodiment, the thickness is set to be 100 to 150 μm. Moreover, upper and lower surfaces of the photosensitive resin film (21) are almost flat. Furthermore, the photosensitive resin film (21) to be the transparent body may be colorless or colored.

The photosensitive resin film (21) is previously backed with a translucent thin resin film (3) having elasticity. The thin resin film (3) has adhesive layers (31) and (32) on both of upper and lower surfaces and the adhesive layer (32) on a lower side is covered with a releasing paper (33) in the same manner as in the conventional art. Although the thin resin film (3) has a smaller thickness than a thickness of the photosensitive resin film (21), that is, approximately 15 to 30 μm, the present invention is not restricted to the thickness.

As shown in FIG. 1, a lower surface of the thin resin film (3) is covered with a masking film (4) and a lower surface of the masking film (4) is exposed to light to form a convex portion as will be described below.

In a convex forming area (40) of the masking film (4), a semi-translucent portion (43) and a translucent portion (41) are formed in sequence at an outside of a light-shielding portion (42) in order to express a shade in gradation (see FIG. 3). Herein, the gradation indicates gradation of lightness, that is, a stage. More specifically, the light-shielding portion (42) is black, the semi-translucent portion (43) is gray and the translucent portion (41) is transparent. In other words, the convex forming area (40) of the masking film (4) has a light transmittance increasing stepwise from the light-shielding portion (42) toward the translucent portion (41). The light transmittance represents a degree in a percentage how much of light is transmitted through the masking film (4).

For convenience of illustration, the semi-translucent portion (43) and the translucent portion (41) are formed in sequence at the outside of the light-shielding portion (42). The light-shielding portion (42), the semi-translucent portion (43) and the translucent portion (41) may be mixed with each other.

The light-shielding portion (42) and the semi-translucent portion (43) are formed by ink jet printing, for example, and a plurality of layers of ink particles (6) to be droplet of a light-shielding material are superposed to form a multilayer as shown in FIG. 2. Consequently, they are formed to eliminate a clearance by which light can be transmitted through the light-shielding portion (42) and to cause the semi-translucent portion (43) to transmit light in a certain partial quantity therethrough.

As a method for forming a black color of the light-shielding portion (42) of this type, a technique referred to as a so-called halftone is known. Referring to the technique, an ink layer is formed as a single layer and a density of the ink layer is varied for unit area to form the light-shielding portion and the translucent portion.

However, there are formed only a part through which light is perfectly transmitted and a part through which the light is not transmitted at all, and there is not formed a semi-translucent portion through which light in a certain partial quantity is transmitted. Accordingly, there is not obtained a non-square shape of a corner portion which is a feature of the present embodiment.

In the present embodiment, therefore, layers of the ink particles (6) are formed as a multilayer to include the light-shielding portion (42) and the translucent portion (41), as well as the semi-translucent portion (43) whose transmittance has a value between those of the light transmittances of the light-shielding portion (42) and the translucent portion (41).

Next, as shown in FIG. 4, the masking film (4) is irradiated with light from a light source (5) from below in a state in which the lower surface of the thin resin film (3) is covered with the masking film (4). When the light is transmitted through the translucent portion (41) and then the photosensitive resin film (21) in a perpendicular direction, the transmitted part of the photosensitive resin film (21) (the part interposed between dashed lines in FIG. 4) is cured in the perpendicular direction.

When the light is transmitted through the semi-translucent portion (43), the photosensitive resin film (21) is cured up to a middle of the thickness. In other words, there is brought into a state in which a cured portion and an uncured portion are mixed with each other.

Even if the light-shielding portion (42) is irradiated with light, the light is not transmitted through the photosensitive resin film (21). Therefore, a part of the photosensitive resin film (21) which corresponds to the light-shielding portion (42) is not cured.

When the masking film (4) is removed after the irradiation with the light source (5), there is obtained the photosensitive resin film (21) having a cured and exposed portion (22) and an uncured and unexposed portion (23) formed thereon.

As shown in FIG. 5, the photosensitive resin film (21) subjected to the exposure to light is washed with a cleaning solution such as water so that the unexposed portion (23) is washed away and a sheet (2) having the exposed portion (22) left in a convex manner is thus obtained. The adjacent exposed portions (22) are not linked to each other.

In this case, when the unexposed portion (23) is removed from the photosensitive resin film (21) subjected to the exposure to light, a part in which the cured portion and the uncured portion are mixed with each other takes such a shape that a corner portion is not square. Consequently, it is possible to vary a height every exposed portion (22) or to give roundness to a corner portion of an upper surface of a convex pattern. Thus, a pattern to be displayed can have softness and warmth.

The sheet (2) having the exposed portion (22) left in the convex manner is dried sufficiently. The sheet (2) is a transparent body because of a necessity of the exposure to light. Therefore, a decoration or a coloration is wholly applied to the sheet (2) so as to hide ground colors of the photosensitive resin film (21) and the thin resin film (3) if necessary. If the decoration is grain, for example, hues of the convex exposed portion (22) and the decoration are well-matched so that grain full of reality can be expressed.

The releasing paper (33) is peeled off and the dried sheet (2) is then pasted onto the product (1) in the same manner as in the conventional art (see FIG. 13). Before the pasting, dirt and an oil content on the surface of the product (1) is removed with solvent, alcohol or the like in order to enhance an adhesive property to the adhesive layer (32) of the sheet. The product (1) is not restricted to a trial product, and is not to a synthetic resin-made product but may be made of wood or metal. A decoration or a coloration may be applied after the sheet (2) is pasted onto the product (1).

It is sufficient that the releasing paper (33) is formed by a translucent thin material.

The sheet having the exposed portion (22) left in the convex manner is backed with the thin resin film (3) so that a strength is increased. Moreover, the exposed portions (22) are linked to each other only through the thin resin film (3). The thin resin film (3) has elasticity. Therefore, the sheet (2) having the exposed portion (22) left in the convex manner is slightly extended if it is pulled. For this reason, the sheet (2) can easily be stuck along a three-dimensional shape of the product (1).

The thin resin film (3) is a double-sided adhesive film. Therefore, time and labor for applying an adhesive to the sheet (2) or the product (1) can be avoided so that a workability of an adhesion can be enhanced. Moreover, the adhesive layer (32) for an adhesion to a surface of a product has a uniform thickness. Therefore, it is possible to facilitate the fine adhesion without causing an adhesion spot due to a partial excess or deficiency of the adhesive.

Depending on three-dimensional concavo-convex portions of the product (1), it is difficult to carry out an adhesion to the surface of the product (1) without causing wrinkles on the sheet (2). In such a case, it is preferable to cut out an extra portion of the sheet (2), thereby carrying out the adhesion so as to prevent the wrinkles from being caused over the product (1).

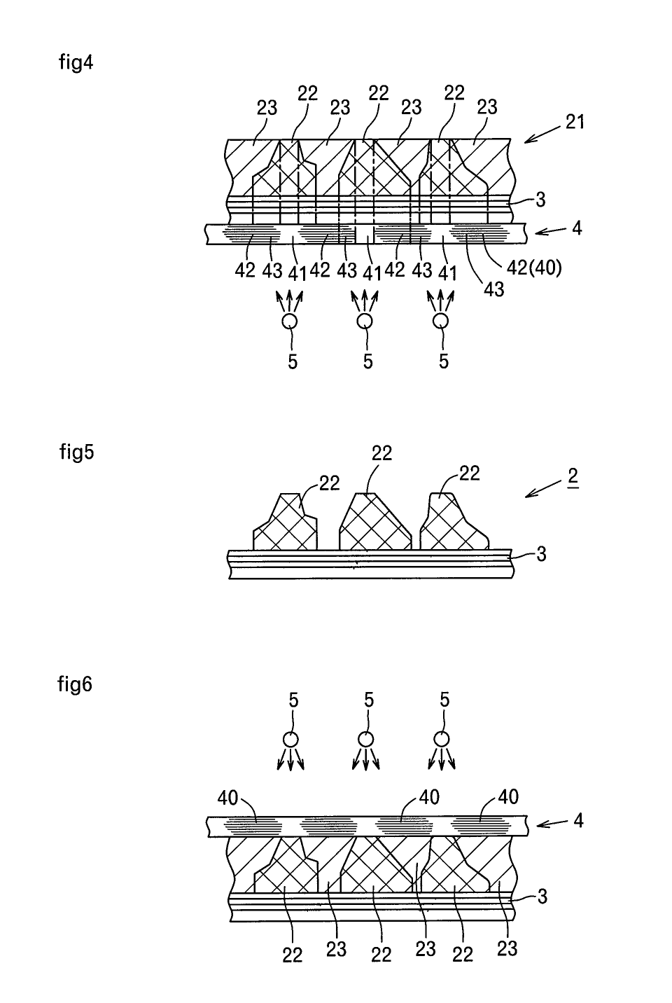

In the above embodiment, the lower side of the photosensitive resin film (21) is exposed to light. As shown in FIG. 6, however, it is also possible that the upper side of the photosensitive resin film (21) is covered with the masking film (4) such that the masking film (4) is exposed to light. In other words, the thin resin film (3) is provided on an opposite side to the masking film (4) with the photosensitive resin film (21) interposed therebetween.

### Second Embodiment

In the present embodiment, the light-shielding portion (42), the semi-translucent portion (43) and the translucent portion (41) in the convex forming area (40) of the masking film (4) are not expressed in a shade, but a light-shielding portion, a semi-translucent portion and a translucent portion are formed through an application of a plurality of colors having different light transmittance, more specifically ultraviolet ray transmittance, respectively. In other words, a convex pattern is formed on the masking film (4) in accordance with color patterns having different light transmittance in place of a shade of an ink.

FIG. 7 is a view showing a relationship between a color and an ultraviolet ray transmittance. As is well known, a purple color is easily passed through by ultraviolet ray, that is, has a high light transmittance, and the light transmittance is gradually decreased in order of the purple color, an indigo blue color, a blue color, a green color, a yellow color, an orange color and a red color.

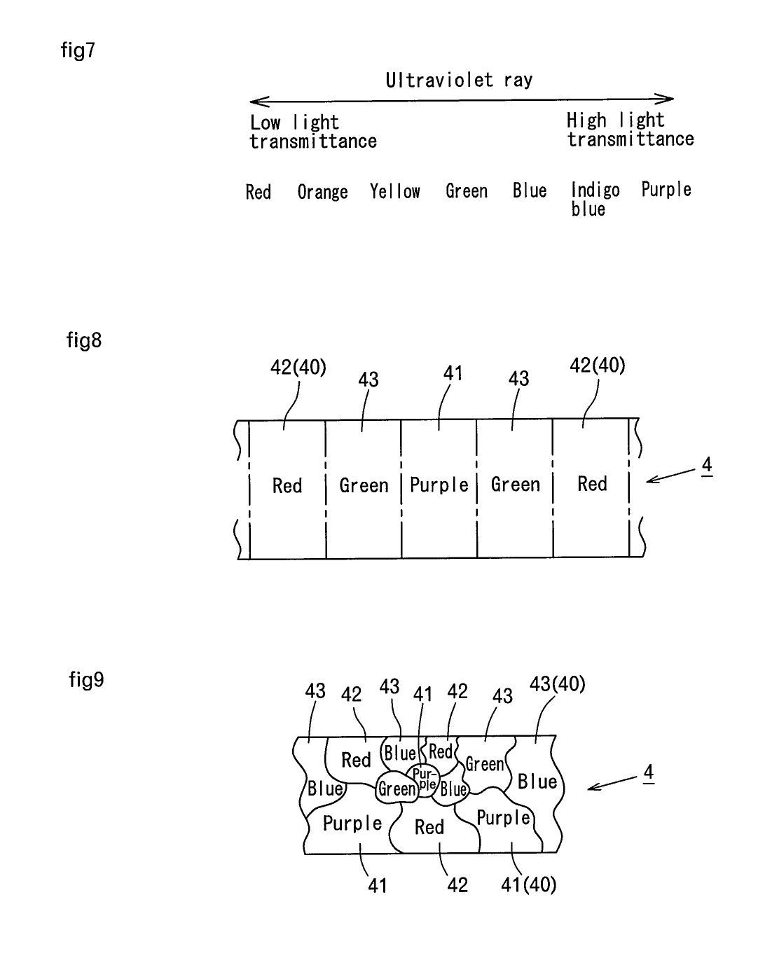

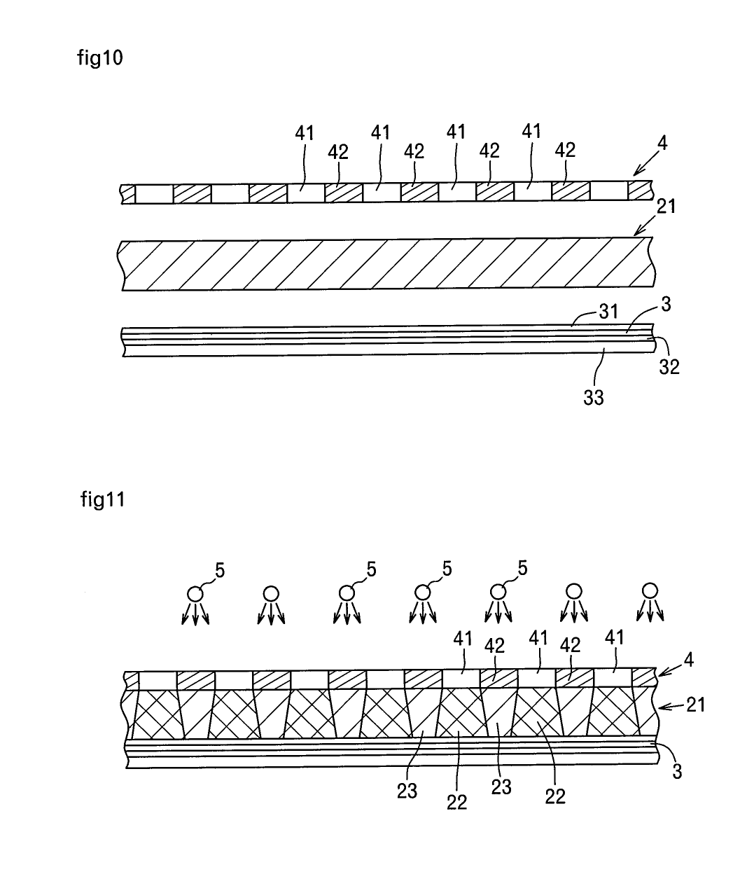

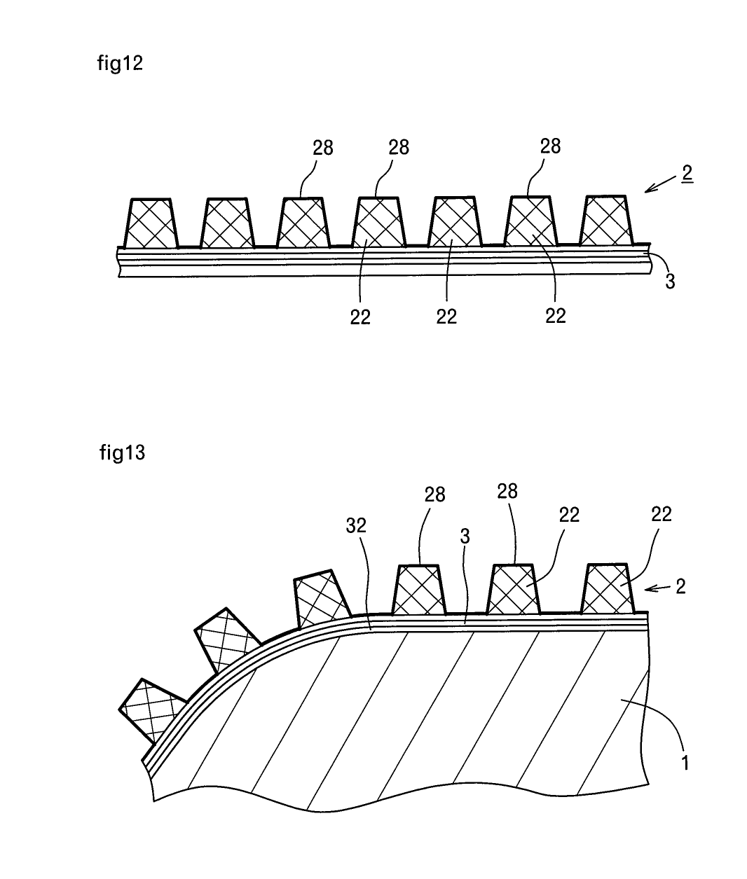

By utilizing the property, as shown in a plan view of FIG. 8, the translucent portion (41) has the purple color with a high light transmittance, for example, the semi-translucent portion (43) has the green color with a slightly low light transmittance, for example, and the light-shielding portion (42) has the red color with the lowest light transmittance. Even if the masking film (4) provided with the convex forming area (40) is used and exposed to light, it is possible to form the sheet (2) which can vary a height every exposed portion (22) or can give roundness to a corner portion of an upper surface of the convex pattern.

The light-shielding portion (42), the semi-translucent portion (43) and the translucent portion (41) are not necessarily arranged in good order in a transverse direction. For example, as shown in a plan view of FIG. 9, the light-shielding portion (42), the semi-translucent portion (43) and the translucent portion (41) may be mixed together.

The translucent portion (41) may have such a color as to irregularly reflect light used for the exposure. The color includes, for example, a milky white color or a yellow color. Whereby, light transmitted through the translucent portion (41) is irregularly reflected so that roundness can be given to the corner portion of the upper surface of the convex exposed portion (22). Consequently, it is possible to enhance an esthetic effect of a sheet having a convex pattern formed thereon.

Moreover, it is also possible to propose that the unexposed portion (23) is not perfectly washed away after the exposure in order to retain the unexposed portion (23) partially. Consequently, it is possible to give the roundness to the corner portion of the upper surface of the convex exposed portion (22). Moreover, it is possible to form a sheet in which the exposed portion (22) and the partially retained unexposed portion (23) are provided together. Thus, it is possible to fabricate a sheet with no constant height of a convex pattern and full of variety.

### DESCRIPTION OF REFERENCE SIGNS

(1) product
(2) sheet
(3) thin resin film
(4) masking film
(21) photosensitive resin film
(22) exposed portion
(40) convex forming area
(41) translucent portion
(42) light-shielding portion
(43) semi-translucent portion

1. A method for forming a convex pattern on a surface of a sheet comprising the steps of:
covering a photosensitive resin film 21 with a masking film 4 having a convex forming area 40 corresponding to a convex pattern to be obtained;
exposing the photosensitive resin film 21 to light from an outside of the masking film 4; and
removing an unexposed portion of the photosensitive resin film 21 subjected to the exposing step, thereby forming a sheet 2 with an exposed portion 22 left, wherein
the convex forming area 40 of the masking film 4 has a light-shielding portion 42, a semi-translucent portion 43 and a translucent portion 41 which have a shade expressed in gradation, and
a light transmittance increases stepwise from the light-shielding portion 42 toward the translucent portion 41.

2. The method according to claim 1, wherein
the semi-translucent portion 43 and the translucent portion 41 are formed in sequence at a side of the light-shielding portion 42.

3. The method according to claim 1 or 2, further comprising the step of
preliminarily backing the photosensitive resin film 21 with a thin resin film 3 before the step of covering the photosensitive resin film 21 with the masking film 4.

4. A method for forming a convex pattern on a surface of a sheet comprising the steps of:
covering a photosensitive resin film 21 with a masking film 4 having a convex forming area 40 corresponding to a convex pattern to be obtained;
exposing the photosensitive resin film 21 to light from an outside of the masking film 4; and
removing an unexposed portion of the photosensitive resin film 21 subjected to the exposing step, thereby forming a sheet 2 with an exposed portion 22 left, wherein
the convex forming area 40 of the masking film 4 has a light-shielding portion 42, a semi-translucent portion 43 and a translucent portion 41 to which colors having different light transmittance of an ultraviolet ray are given respectively, and
the light transmittance increases stepwise from the light-shielding portion 42 toward the translucent portion 41.

5. The method according to claim 3, wherein
the thin resin film 3 is a double-sided adhesive film, on both surfaces of which adhesive layers 31 and 32 are provided, and the adhesive layer 31 adheres to the photosensitive resin film 21 and the other adhesive layer 32 adheres to a product 1.

6. The method according to claim 5, further comprising the step of applying a coating to a convex-patterned surface of the sheet 2 before the thin resin film 3 adheres to the product 1.

7. The method according to claim 5 or 6, further comprising the step of applying a coating to the sheet 2 adhering to a surface of the product 1.

8. A sheet having a surface provided with a convex pattern formed by the method according to any of claims 1 to 7.

9. The method according to claim 1, wherein
the translucent portion 41 has such a color as to irregularly reflect transmitted light.
